(19) United States
(12) Patent Application Publication
(10) Pub. No.: US 2006/0162903 A1
(43) Pub. Date: Jul. 27, 2006

(54) Liquid cooled thermosiphon with flexible partition

(76) Inventors: Mohinder Singh Bhatti, Amherst, NY (US); Shrikant Mukund Joshi, Williamsville, NY (US); Mark Joseph Parisi, East Amherst, NY (US); Russell S. Johnson, Tonawanda, NY (US)

Correspondence Address: PATRICK M. GRIFFIN;DELPHI TECHNOLOGIES, INC., Legal Staff, Mail Code: 480-410-202, P.O. Box 5052, Troy, MI, 48007-5052, US

(21) Appl. No.: 11/040,988

(22) Filed: Jan. 21, 2005

(51) Int. Cl. H05K 7/20

(52) U.S. Cl. 165/104.14; 165/104.21; 165/104.33; 361/700

(57) ABSTRACT

A fluid heat exchanger assembly cools an electronic device with a cooling fluid supplied from a heat extractor to an upper portion of a housing. A refrigerant is disposed in a lower portion of the housing for liquid-to-vapor transformation. A partition divides the upper portion of the housing from the lower portion and is flexible to vary the volume of the upper portion for modulating the flow of coolant fluid through the upper portion in response to heat transferred by an electronic device to the lower portion of the housing.

### RELATED APPLICATIONS

The subject invention is related to the inventions disclosed in co-pending applications DP-311408 (H&H 60408-567) and DP-312789 (H&H 60408-597), filed concurrently herewith.

### BACKGROUND OF THE INVENTION

1. Field of the Invention

A fluid heat exchanger assembly for cooling an electronic device.

2. Description of the Prior Art

Research activities have focused on developing assemblies to efficiently dissipate heat from electronic devices that are highly concentrated heat sources, such as microprocessors and computer chips. These electronic devices typically have power densities in the range of about 5 to 35 W/cm² and relatively small available space for placement of fans, heat exchangers, heat sink assemblies and the like. However, these electronic devices are increasingly being miniaturized and designed to achieve increased computing speeds that generate heat up to 200 W/cm².

Heat exchangers and heat sink assemblies have been used that apply natural or forced convection cooling methods to cool the electronic devices. These heat exchangers typically use air to directly remove heat from the electronic devices. However, air has a relatively low heat capacity. Such heat sink assemblies are suitable for removing heat from relatively low power heat sources with power density in the range of 5 to 15 W/cm². The increased computing speeds result in corresponding increases in the power density of the electronic devices in the order of 20 to 35 W/cm² thus requiring more effective heat sink assemblies.

In response to the increased heat to be dissipated, liquid-cooled units called LCUs employing a cold plate in conjunction with high heat capacity fluids, like water and water-glycol solutions, have been used to remove heat from these types of high power density heat sources. One type of LCU circulates the cooling liquid so that the liquid removes heat from the heat source, like a computer chip, affixed to the cold plate, and is then transferred to a remote location where the heat is easily dissipated into a flowing air stream with the use of a liquid-to-air heat exchanger and an air moving device such as a fan or a blower. These types of LCUs are characterized as indirect cooling units since they remove heat from the heat source indirectly by a secondary working fluid, generally a single-phase liquid, which first removes heat from the heat source and then dissipates it into the air stream flowing through the remotely located liquid-to-air heat exchanger. Such LCUs are satisfactory for moderate heat flux less than 35 to 45 W/cm² at the cold plate.

In the prior art heat sinks, such as those disclosed in U.S. Pat. Nos. 6,422,307 and 5,304,846, the single-phase working fluid of the liquid cooled unit (LCU) flows directly over the cold plate causing cold plate corrosion and leakage problems.

As computing speeds continue to increase even more dramatically, the corresponding power densities of the devices rise up to 200 W/cm². The constraints of the miniaturization coupled with high heat flux generated by such devices call for extremely efficient, compact, and reliable thermosiphon cooling units called TCUs. Such TCUs perform better than LCUs above 45 W/cm² heat flux at the cold plate. A typical TCU absorbs heat generated by the electronic device by vaporizing the captive working fluid on a boiler plate of the unit. The boiling of the working fluid constitutes a phase change from liquid-to-vapor state and as such the working fluid of the TCU is considered to be a two-phase fluid. The vapor generated during boiling of the working fluid is then transferred to an air-cooled condenser, in close proximity to the boiler plate, where it is liquefied by the process of film condensation over the condensing surface of the TCU. The heat is rejected into an air stream flowing over a finned external surface of the condenser. The condensed liquid is returned back to the boiler plate by gravity to continue the boiling-condensing cycle. These TCUs require boiling and condensing processes to occur in close proximity to each other thereby imposing conflicting thermal conditions in a relatively small volume.

Examples of cooling systems for electronic devices are disclosed in U.S. Pat. No. 4,704,658 to Yokouchi et al; U.S. Pat. No. 5,529,115 to Paterson and U.S. Pat. No. 5,704,416 to Larson et al.

### SUMMARY OF THE INVENTION AND ADVANTAGES

In accordance with the subject invention, heat generated by an electronic device is transferred to the lower portion of a housing having a refrigerant therein for liquid-to-vapor transformation as coolant fluid flows over a flexible partition in an upper portion of the housing to vary the volume of the upper portion for modulating the flow of coolant fluid through the upper portion in response to heat transferred by the electronic device to the lower portion of the housing.

The invention employs a flexible partition to separate the secondary two-phase fluid from the single-phase working fluid of the LCU. The flexible partition performs the useful function of changing the volume of the upper portion or boiling chamber depending on the chip heat flux. As the chip heat flux increases, the flexible partition expands upward decreasing the volume of the upper portion thereby increasing the coolant flow velocity and heat transfer rate. As the chip heat flux decreases, the flexible partition contracts increasing the volume of the upper portion thereby decreasing the coolant flow velocity and heat transfer rate. Thus, the flexible partition continuously regulates the working fluid flow velocity through the upper portion thereby adjusting the heat transfer rate in response to computer cooling demand.

The present invention utilizes a captive secondary fluid capable of undergoing liquid-to-vapor transformation within the boiling chamber to remove heat by ebullition from the cold plate. The resulting vapor fills the lower portion or boiling chamber under the flexible or bellows type partition which separates the working fluid of the upper portion from the secondary fluid vapor in the lower portion or boiling chamber. The secondary fluid vapor is condensed by the working fluid over the flexible partition surface. Thus the lower portion or boiling chamber with the secondary two-phase fluid functions as a thermosiphon with superincumbent cooling chamber defined by the flexible partition serving as the condenser partition.

The heat transfer rate of the two-phase secondary fluid is inherently higher than that of the single-phase working fluid. Therefore, besides enhancing the cooling capacity of the TCU, the invention solves the problem of corrosion and leakage that plagues the LCU with highly aggressive working fluid flowing directly over the cold plate. The captive two-phase secondary fluid in direct contact with the cold plate is not as aggressive as the working fluid of the LCU.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective view of the heat exchanger of the subject invention;

FIG. 2 is a cross sectional view of the heat exchanger shown in FIG. 1; and

FIG. 3 is a schematic of a liquid cooling system in which the heat exchanger of the subject invention may be utilized.

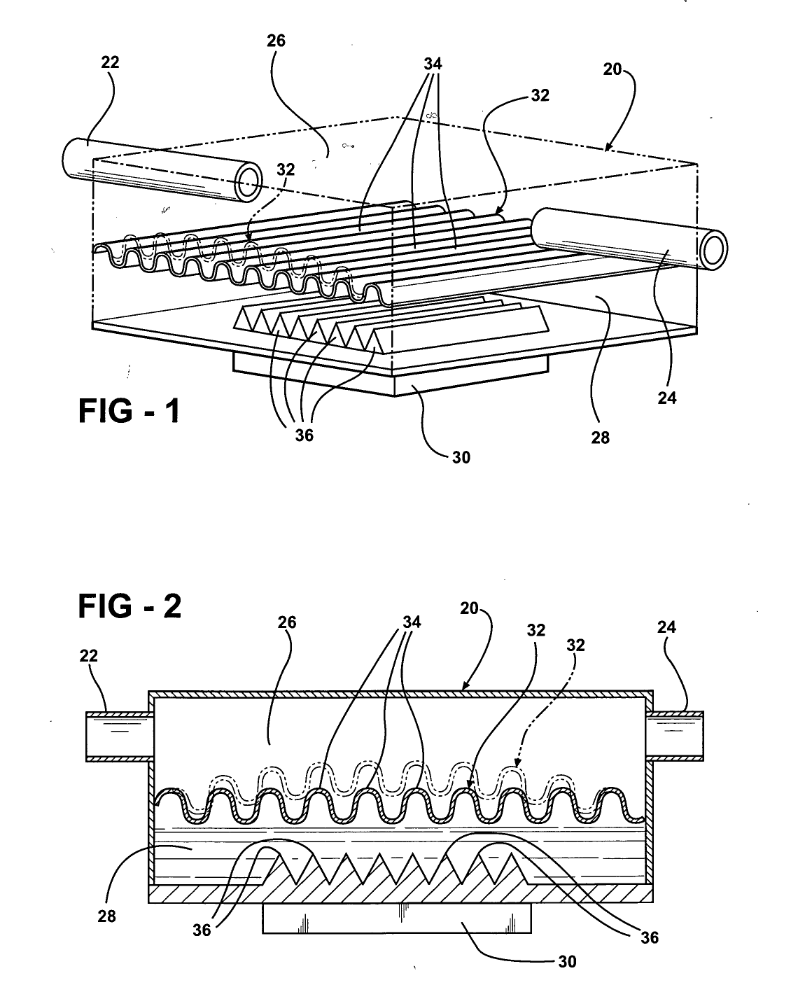

### DETAILED DESCRIPTION OF THE PREFERRED EMBODIMENT

A fluid heat exchanger assembly comprises a housing 20 having an inlet 22 and an outlet 24 and an upper portion 26 and a lower portion 28 extending between the inlet 22 and the outlet 24 for establishing a direction of flow from the inlet 22 to the outlet 24. The assembly is used to cool an electronic device 30 engaging or secured to the lower portion 28 of the housing 20.

A partition 32 divides the housing 20 into the upper portion 26 and the lower portion 28 for establishing a direction of flow of coolant liquid from the inlet 22 to the outlet 24 in the upper portion 26.

The housing 20 is hermetically sealed about the partition 32 to contain a refrigerant in the lower portion 28 for liquid-to-vapor transformation. In other words, the partition 32 separates the refrigerant in the lower portion 28 from the coolant fluid in the upper portion 26. The partition 32 is flexible to vary the volume of the upper portion 26 for modulating the flow of coolant fluid through the upper portion 26 in response to heat transferred by an electronic device to the lower portion 28 of the housing 20.

The partition 32 defines a cross section having undulations 34 for expanding and contracting in response to the pressure of coolant flow through the upper portion 26. The partition 32 is undulated or corrugated in the direction of flow from the inlet 22 to said outlet 24 so that the coolant flows across the undulations 34. The partition 32 may comprise a thin gage metal, although various materials may be utilized that are inert to the coolant and the refrigerant. As the heat flux from the electronic device increases, the flexible partition 32 expands upward decreasing the volume of the upper portion 26 thereby increasing the coolant flow velocity between the inlet 22 and the outlet 24. As the heat flux from the electronic device decreases, the flexible partition 32 contracts increasing the volume of the upper portion 26 thereby decreasing the coolant flow velocity. Thus, the flexible partition 32 continuously regulates the coolant fluid flow velocity through the upper portion 26 thereby adjusting the heat transfer rate in response to computer cooling demand.

A plurality of fins 36 extend from the bottom of the housing 20 for increasing heat transfer from the electronic device 30 to the interior of the lower portion 28 of the housing 20. The fins 36 extend linearly across the direction of flow under the partition 32 and between the inlet 22 and the outlet 24 in the upper portion 26. The heat transfer fins 36 are disposed in the lower portion 28 of the housing 20 for transferring heat from the electronic device disposed on the exterior of the lower portion 28 of the housing 20. The fins 36 would be like those shown in U.S. Pat. No. 6,588,498.

The upper portion 26 of the housing 20 is generally rectangular and the lower portion 28 of the housing 20 is generally rectangular and and generally coextensive with the upper portion 26. In other words, the housing 20 is generally a square in both the upper 26 and lower portions 28 and the upper portion 26 has the same footprint as the lower portion 28.

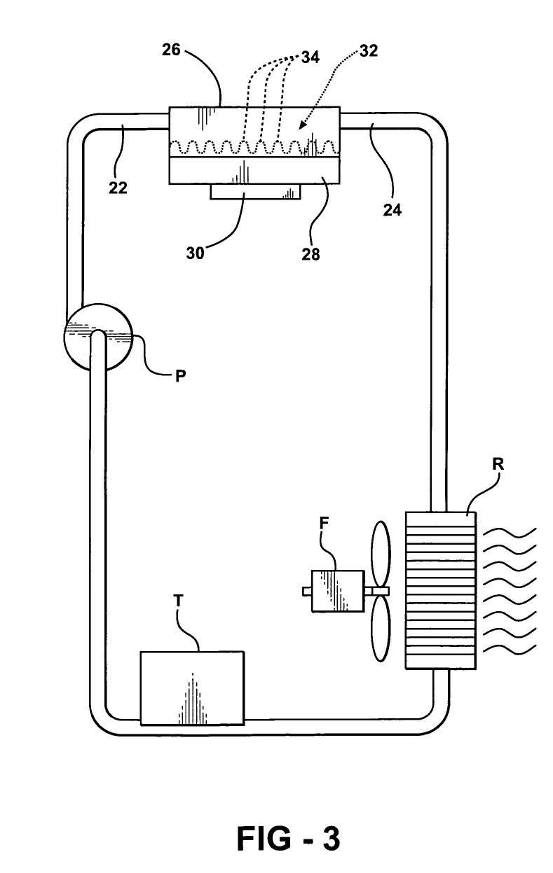

The operation of the heat exchanger housing 20 is incorporated into a liquid cooling system as illustrated in FIG. 3. The electronic device generates an amount of heat to be dissipated and the heat is transferred from the electronic device to the bottom of the heat exchanger housing 20. The heat is then conducted from the bottom to the fins 36 and thence to the refrigerant. A working fluid mover, such as a pump P, moves a cooling fluid, usually a liquid, through a cooling fluid storage tank T, that stores excess cooling fluid. The pump P moves the cooling fluid through a heat extractor or radiator assembly to dissipate heat from the cooling fluid, the heat extractor or radiator assembly including a fan F and radiator R. The radiator R can be of the well known type including tubes with cooling tins between the tubes to exchange heat between the cooling fluid passing through the tubes and air forced through the radiator by the fan F.

The invention therefore provides a method of cooling an electronic device by disposing a refrigerant in the lower portion 28 of the housing 20 for liquid-to-vapor transformation and transferring the heat generated by the electronic device to the lower portion 28 of a housing 20. The method is distinguished by flowing coolant fluid over the upper portion 26 of the housing 20 and varying the volume of the upper portion 26 of the housing 20 for modulating the flow of coolant fluid through the partition 32 in response to heat transferred by an electronic device to the lower portion 28 of the housing 20. The method may be further defined as extending and contracting the partition 32 to vary the volume of the upper portion 26.

Obviously, many modifications and variations of the present invention are possible in light of the above teachings. The invention may be practiced otherwise than as specifically described within the scope of the appended claims, wherein recitations should be interpreted to cover any combination in which the incentive novelty exercises its utility.

1. A fluid heat exchanger assembly for cooling an electronic device with a cooling fluid supplied from a heat extractor and comprising;
a housing having an inlet and an outlet and an upper portion and a lower portion with said inlet and said outlet being in said upper portion,
a partition dividing said housing into said upper portion and said lower portion for establishing a direction of flow of coolant fluid from said inlet to said outlet in said upper portion,
a refrigerant disposed in said lower portion of said housing for liquid-to-vapor transformation,
said housing being hermetically sealed about said partition to separate said refrigerant in said lower portion from said coolant fluid in said upper portion, and
said partition being flexible to vary the volume of said upper portion for modulating the flow of coolant fluid through said upper portion in response to heat transferred by an electronic device to said lower portion of said housing.

2. An assembly as set forth in claim 1 wherein said partition defines a cross section having undulations for expanding and contracting.

3. An assembly as set forth in claim 2 wherein said partition comprises a thin gage metal.

4. An assembly as set forth in claim 2 wherein said partition is undulated in said direction of flow from said inlet to said outlet.

5. An assembly as set forth in claim 1 including heat transfer fins disposed in said lower portion of said housing for transferring heat from an electronic device disposed on the exterior of said lower portion of said housing.

6. An assembly as set forth in claim 1 wherein said upper portion of said housing is generally rectangular and said lower portion of said housing is generally coextensive with said upper portion.

7. A method of cooling an electronic device comprising the steps of;
generating heat by an electronic device,
transferring the heat generated by the electronic device to the lower portion of a housing,
disposing a refrigerant in the lower portion of the housing for liquid-to-vapor transformation, and
flowing coolant fluid over a flexible partition in an upper portion of the housing and varying the volume of the upper portion of the housing for modulating the flow of coolant fluid through the partition in response to heat transferred by an electronic device to the lower portion of the housing.

8. A method as set forth in claim 7 including extending and contracting the partition to vary the volume of the upper portion.
